(19) United States
(12) Patent Application Publication
(10) Pub. No.: US 2008/0057643 A1
(43) Pub. Date: Mar. 6, 2008

(54) Memory and method of reducing floating gate coupling

(75) Inventor: Seiichi Aritome, Boise, ID (US)

Correspondence Address: LEFFERT JAY & POLGLAZE, P.A.;Attn: Daniel J. Polglaze, P. O. Box 581009, Minneapolis, MN, 55402, US

(73) Assignee: Micron Technology, Inc.

(21) Appl. No.: 11/511,669

(22) Filed: Aug. 29, 2006

(51) Int. Cl. H01L 21/336

(52) U.S. Cl. 438/257

(57) ABSTRACT

Reduction in floating gate to floating gate coupling in non-volatile memories is accomplished with a conductor interposed between floating gates of adjacent memory cells, the conductor connected to a common source/drain region between adjacent cells, and spaced apart from the floating gates and control gates of adjacent memory cells to reduce tunneling or breakdown between the conductor and the floating and control gates.

### FIELD

The present disclosure relates generally to semiconductor memories and in particular the present disclosure relates to floating gate coupling in non-volatile memories.

### BACKGROUND

Memory devices are typically provided as internal, semiconductor, integrated circuits in computers or other electronic devices. There are many different types of memory including random-access memory (RAM), read only memory (ROM), dynamic random access memory (DRAM), synchronous dynamic random access memory (SDRAM), and flash memory.

Flash memory devices have developed into a popular source of non-volatile memory for a wide range of electronic applications. Flash memory devices typically use a one-transistor memory cell that allows for high memory densities, high reliability, and low power consumption. Common uses for flash memory include personal computers, personal digital assistants (PDAs), digital cameras, and cellular telephones. Program code and system data such as a basic input/output system (BIOS) are typically stored in flash memory devices for use in personal computer systems.

As the performance and complexity of electronic systems increase, the requirement for additional memory in a system also increases. This can be accomplished by increasing the memory density of an integrated circuit by using such technologies as multilevel cells (MLC). For example, MLC NAND flash memory is a very cost effective non-volatile memory.

Multilevel cells take advantage of the analog nature of a traditional flash cell by assigning a bit pattern to a specific threshold voltage (Vt) range stored on the cell. This technology permits the storage of two or more bits per cell, depending on the quantity of voltage ranges assigned to the cell and the stability of the assigned voltage ranges during the lifetime operation of the memory cell. One problem with MLC devices, however, is the floating gate-to-floating gate coupling that occurs along the same bitline. This coupling can cause the already small margins between states to disappear and the Vₜ distributions to overlap, thus causing errors in reading data.

In NAND memories, coupling between the floating gates of cells, especially those on the same physical word lines of the memory, can be a problem. The problem continues to increase as the distance between floating gates decreases with decreasing memory sizes and tightening tolerances. As structures are positioned closer together, the potential for interference between adjacent structures increases. An example of such interference is interference between floating gates of a semiconductor memory. Because of capacitive coupling, the cells that are adjacent to a cell storing a charge are prone to having their threshold voltages (Vₜ) raised. If the adjacent cells have their threshold voltages raised too high, an unprogrammed cell might appear as being programmed. The increased capacitive coupling between the floating gates can affect the verification, reading, and erasing of adjacent cells.

For the reasons stated above, and for other reasons stated below which will become apparent to those skilled in the art upon reading and understanding the present specification, there is a need in the art for decreased coupling between floating gates in non-volatile memories.

### BRIEF DESCRIPTION OF DRAWINGS

FIG. 1 is a side elevation view of a memory cell according to one embodiment;

FIG. 2 is a top view of a memory array according to another embodiment;

FIG. 3 is a side elevation view of a memory along a word line (CG) according to another embodiment;

FIG. 4 is a functional block diagram of an electrical system having at least one memory device with a memory array configuration according to one embodiment; and

FIG. 5 is a functional block diagram of a memory module having at least one memory device in accordance with another embodiment.

### DETAILED DESCRIPTION

In the following detailed description of the embodiments, reference is made to the accompanying drawings that form a part hereto. In the drawings, like numerals describe substantially similar components throughout the several views. These embodiments are described in sufficient detail to enable those skilled in the art to practice the embodiments. Other embodiments may be utilized and structural, logical, and electrical changes may be made without departing from the scope.

The following detailed description is, therefore, not to be taken in a limiting sense, and the scope is defined only by the appended claims, along with the full range of equivalents to which such claims are entitled.

In the various embodiments, non-volatile memory structures have a conductor interposed between floating gates of adjacent memory cells. The conductor serves to reduce coupling between adjacent floating gates.

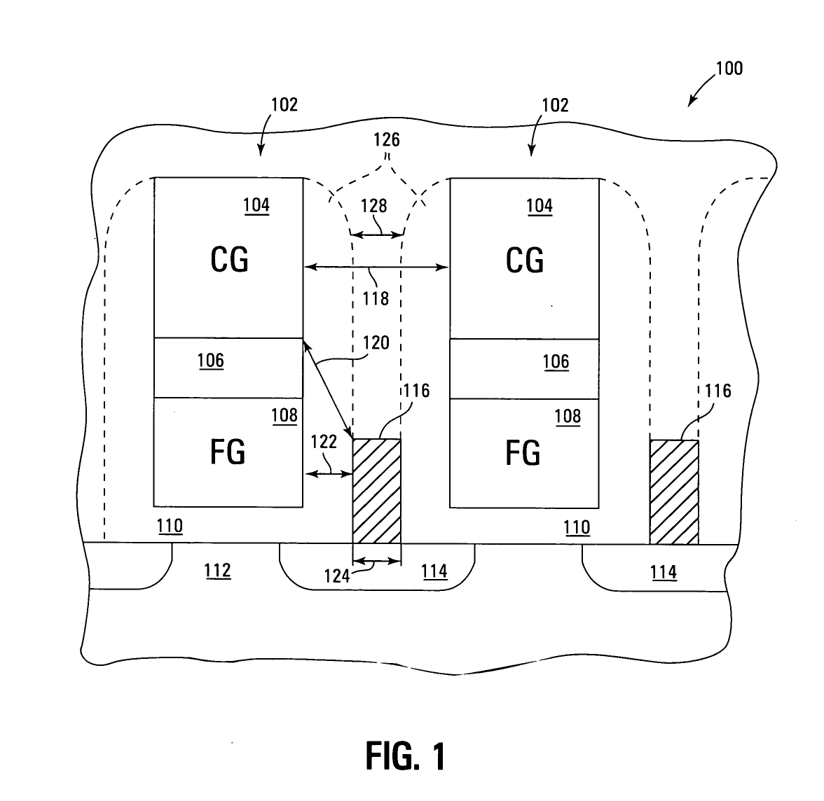

A floating gate memory structure is formed in one embodiment as follows. In one embodiment, a stacked gate structure 100 such as that shown in FIG. 1 is formed. Each stack 102 of the structure 100 includes a control gate 104, an oxide-nitride-oxide (ONO) layer 106, a floating gate 108, and a tunnel oxide layer 110 over a substrate 112. Adjacent stacks 102 of stacked gate structures are arranged as shown, with adjacent stacks sharing a common source/drain region 114. A conductor 116 is formed in one embodiment above and connected to the source/drain region 114 between two stacks 102, and interposed between adjacent floating gates 108 of the structure 100. The conductor 116 can be formed of polysilicon or another conductor by methods including but not limited to selective growth, or blanket deposition and etch back. The conductor 116 (which also may be referred to as a shield, plug, or pillar) is in one embodiment positioned to reduce coupling between adjacent floating gates 108 of adjacent stacks 102 in the structure 100.

For example, in one embodiment, sidewalls 126 of Silicon Dioxide (SiO₂) are deposited, using known deposition techniques, surrounding the stacked cells 102 to a thickness equal to that of the gap 122 to be formed between the conductor 116 and the floating gates 108. Following that, the conductor 116 is formed in the gap 128 between the sidewalls 126, and the sidewalls 126 are removed by a process such as reactive ion etching (RIE).

The positioning and size of the conductor 116 depends upon the thicknesses of the tunnel oxide 110 and ONO 106 layers of the stacks 102 (typically approximately 8 nanometers and 15-25 nanometers, respectively), as well as the gap 118 between adjacent floating gates. In one embodiment, the closest distance 120 of any portion of the conductor 116 from a control gate is at greater than the combined thicknesses of the ONO and tunnel oxide layers 106 and 110. This prevents unwanted tunneling current between the conductor 116 and the control gate 104, as well as breakdown between the conductor 116 and the control gate 104. For example, in a programming operation, a control gate such as gate 104 has a potential of 20 volts applied to it. The source/drain region and substrate are typically at 0 volts.

The conductor 116 being connected to the source/drain region, there is a potential for tunneling current between the conductor 116 and the control gate 104 due to the potential difference. By making the separation 120 between the control gate 104 and the conductor 116 at least equal to the combined thickness of the ONO and tunnel oxide layers, this tunneling is avoided. Further, the conductor 116 between adjacent floating gates 108 of the structure (such as structure 100) reduces the floating gate to floating gate coupling along the bitlines of the structure.

In order to prevent tunneling or breakdown between the conductor 116 and an adjacent floating gate 108, in one embodiment, the closest distance 122 of any portion of the conductor 116 from a floating gate is at least as great as the thickness of the tunnel oxide layer 110. For example, typical 35 nanometer (nm) memories have a gap between adjacent floating gates of approximately 35 nm and a tunnel oxide thickness of about 8 nm. For this configuration, the conductor 116 can have a thickness up to 19 nm, leaving an 8 nm gap on either side of the conductor between adjacent floating gates.

The width 124 of the conductor 116 is less important than the gap distance 122. This distance 122 prevents leakage between the conductor 116 and the floating gates 108. Depending upon the width of the conductor 116, and the separation distance 122, the height of the conductor is determined by geometry in order to allow it to meet the spacing 120 between the conductor 116 and the control gates 104.

While dimensions have been recited for purposes of example, it should be understood that the dimensions of floating gate structures, gaps, layer thicknesses, and the like, are continuously changing. As sizes change, the conductor structure 116 described above continues to be amenable to use with reduction of floating gate coupling, provided adjustments are made to the dimensions to keep the distance 120 greater than the combined thickness of the ONO and tunnel oxide layers (106 and 110), and to keep the distance 122 at least as great as the thickness of the tunnel oxide layer 110.

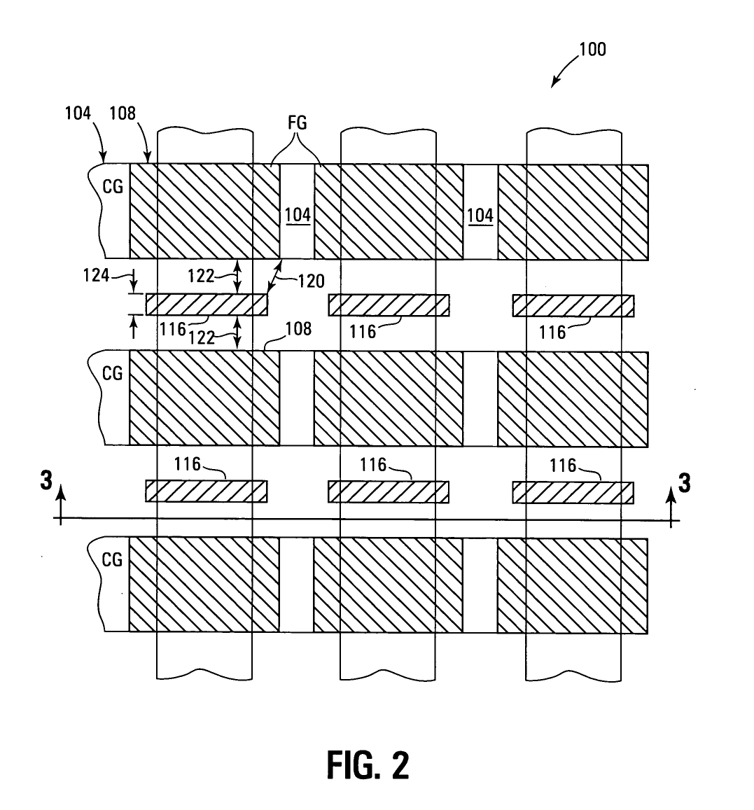

FIG. 2 is a top view of a memory array 200 according to an embodiment. FIG. 200 shows the arrangement of a plurality of conductors 116 and the distance gaps 120 and 122 in a top down view of the array 200. Each conductor 116 creates a conductive barrier between adjacent floating gates 108. Each conductor 116 is isolated from other conductors of the array so that the source/drain regions of cells are not shorted together, and is connected only to the source/drain region common to its adjacent floating gates.

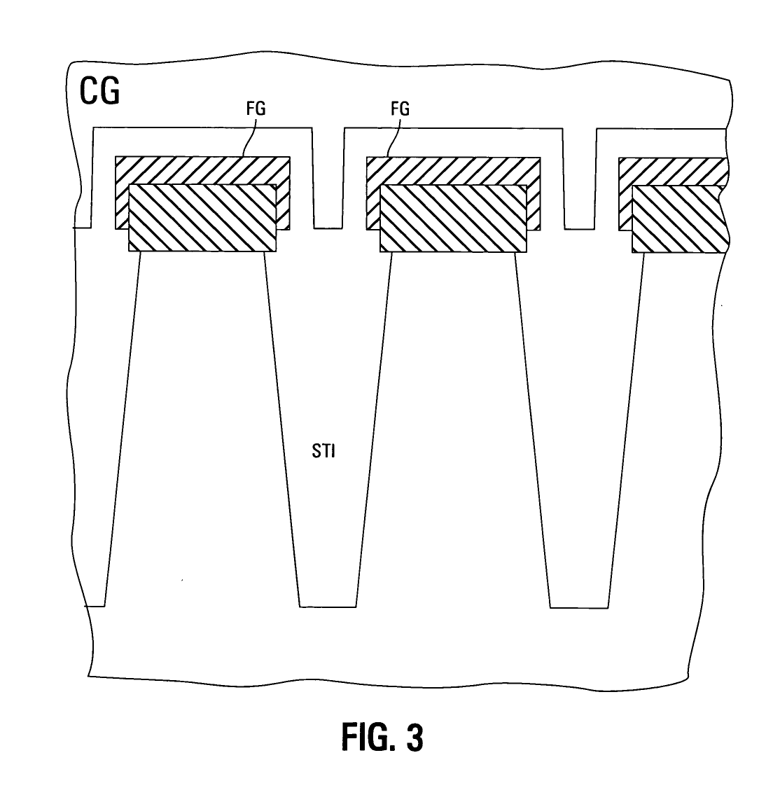

FIG. 3 is a cross-sectional view of the array 200 taken along line 3-3 of FIG. 2, that is along the wordline.

In another embodiment, the conductors, such as conductors 116, do not extend above the top of the control gates 104.

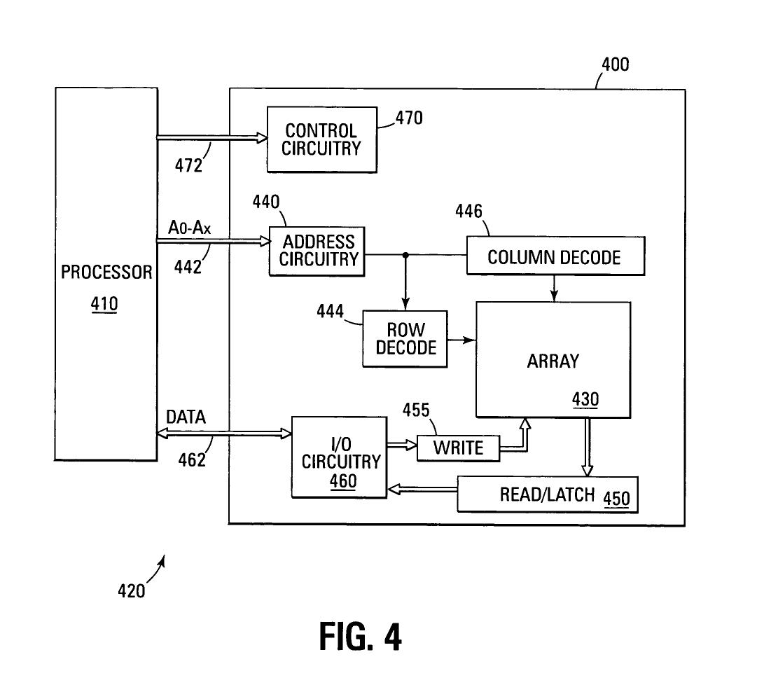

FIG. 4 is a functional block diagram of a memory device 400, such as a flash memory device, of one embodiment of the present invention, which is coupled to a processor 410. The memory device 400 and the processor 410 may form part of an electronic system 420. The memory device 400 has been simplified to focus on features of the memory that are helpful in understanding the embodiments of the present invention. The memory device includes an array of memory cells 430 having conductor structures to reduce floating gate to floating gate coupling such as those shown in FIGS. 1-3 and described above. The memory array 430 is arranged in banks of rows and columns.

An address buffer circuit 440 is provided to latch address signals provided on address input connections AO-Ax 442. Address signals are received and decoded by row decoder 444 and a column decoder 446 to access the memory array 430. It will be appreciated by those skilled in the art, with the benefit of the present description, that the number of address input connections depends upon the density and architecture of the memory array. That is, the number of addresses increases with both increased memory cell counts and increased bank and block counts.

The memory device reads data in the array 430 by sensing voltage or current changes in the memory array columns using sense/latch circuitry 450. The sense/latch circuitry, in one embodiment, is coupled to read and latch a row of data from the memory array. Data input and output buffer circuitry 460 is included for bi-directional data communication over a plurality of data (DQ) connections 462 with the processor 410, and is connected to write circuitry 455 and read/latch circuitry 450 for performing read and write operations on the memory 400.

Command control circuit 470 decodes signals provided on control connections 472 from the processor 410. These signals are used to control the operations on the memory array 430, including data read, data write, and erase operations. The flash memory device has been simplified to facilitate a basic understanding of the features of the memory. A more detailed understanding of internal circuitry and functions of flash memories are known to those skilled in the art.

The memory device 400 includes an array of floating gate memory cells arranged in rows and columns such that the rows are each coupled to a word line and the columns are each coupled to a bitline, control circuitry to read, write and erase the memory cells, address circuitry to latch address signals provided on address input connections, and a conductor interposed between floating gates of the memory. The conductor is connected to a common source/drain region between adjacent floating gates of the array. The conductor is separated in one embodiment from the control gates of adjacent memory cells by a gap having a size at least as great as the sum of the combined thickness of the tunnel oxide and oxide-nitride-oxide layers. The conductor is also separated in one embodiment from the floating gates of adjacent memory cells by a gap at least equal to the thickness of the tunnel oxide.

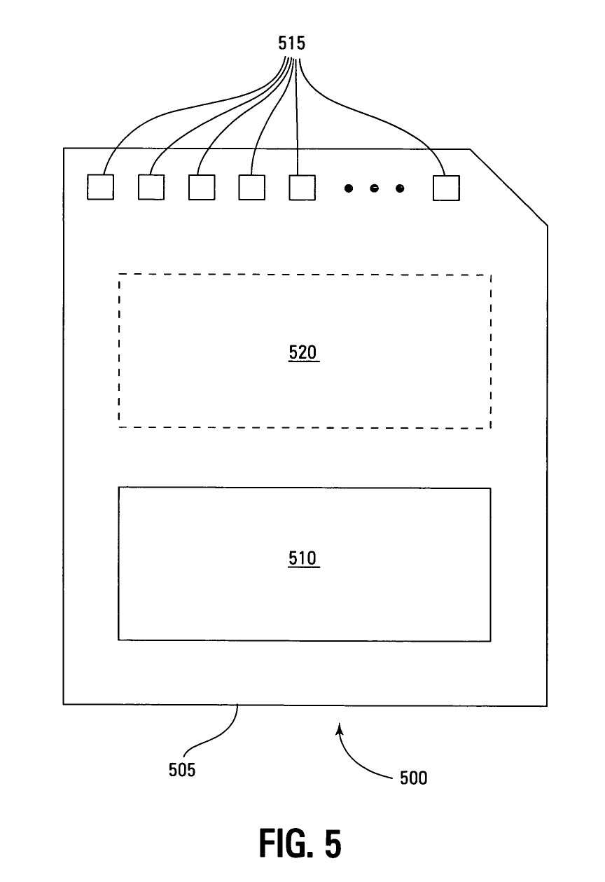

FIG. 5 is an illustration of an exemplary memory module 500. Memory module 500 is illustrated as a memory card, although the concepts discussed with reference to memory module 500 are applicable to other types of removable or portable memory, e.g., USB flash drives, and are intended to be within the scope of “memory module” as used herein. In addition, although one example form factor is depicted in FIG. 5, these concepts are applicable to other form factors as well.

In some embodiments, memory module 500 will include a housing 505 (as depicted) to enclose one or more memory devices 510, though such a housing is not essential to all devices or device applications. At least one memory device 510 is a non-volatile memory including a conductor structure according to various embodiments. Where present, the housing 505 includes one or more contacts 515 for communication with a host device. Examples of host devices include digital cameras, digital recording and playback devices, PDAs, personal computers, memory card readers, interface hubs and the like. For some embodiments, the contacts 515 are in the form of a standardized interface. For example, with a USB flash drive, the contacts 515 might be in the form of a USB Type-A male connector. For some embodiments, the contacts 515 are in the form of a semi-proprietary interface. In general, however, contacts 515 provide an interface for passing control, address and/or data signals between the memory module 500 and a host having compatible receptors for the contacts 515.

The memory module 500 may optionally include additional circuitry 520 which may be one or more integrated circuits and/or discrete components. For some embodiments, the additional circuitry 520 may include a memory controller for controlling access across multiple memory devices 510 and/or for providing a translation layer between an external host and a memory device 510. For example, there may not be a one-to-one correspondence between the number of contacts 515 and a number of I/O connections to the one or more memory devices 510. Thus, a memory controller could selectively couple an I/O connection (not shown in FIG. 5) of a memory device 510 to receive the appropriate signal at the appropriate I/O connection at the appropriate time or to provide the appropriate signal at the appropriate contact 515 at the appropriate time. Similarly, the communication protocol between a host and the memory module 500 may be different than what is required for access of a memory device 510. A memory controller could then translate the command sequences received from a host into the appropriate command sequences to achieve the desired access to the memory device 510. Such translation may further include changes in signal voltage levels in addition to command sequences.

The additional circuitry 520 may further include functionality unrelated to control of a memory device 510 such as logic functions as might be performed by an ASIC (application specific integrated circuit). Also, the additional circuitry 520 may include circuitry to restrict read or write access to the memory module 500, such as password protection, biometrics or the like. The additional circuitry 520 may include circuitry to indicate a status of the memory module 500. For example, the additional circuitry 520 may include functionality to determine whether power is being supplied to the memory module 500 and whether the memory module 500 is currently being accessed, and to display an indication of its status, such as a solid light while powered and a flashing light while being accessed. The additional circuitry 520 may further include passive devices, such as decoupling capacitors to help regulate power requirements within the memory module 500.

### CONCLUSION

A structure and method for reducing floating gate coupling in a non-volatile memory has been described that includes a conductor positioned between adjacent floating gates in a non-volatile memory. The conductor is formed to allow a specified distance gap between the conductor and control gates of the structure, as well as between the conductor and floating gates of the structure.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the embodiments. Therefore, it is manifestly intended that the embodiments be limited only by the claims and the equivalents thereof.

What is claimed is:

1. A method of reducing floating gate coupling in a memory, comprising:
forming a conductor interposed between adjacent floating gates of the memory, the conductor connected only to a source/drain region common to the adjacent floating gates.

2. The method of claim 1, wherein forming a conductor further comprises:
separating the conductor from adjacent control gates to prevent breakdown or tunneling between the conductor and the control gates.

3. The method of claim 1, wherein forming a conductor further comprises:
separating the conductor from adjacent floating gates to prevent breakdown or tunneling between the conductor and the floating gates.

4. The method of claim 2, wherein the memory includes stacks of cells each having a tunnel oxide, a floating gate, an oxide-nitride-oxide layer, and a control gate, and wherein separating comprises:
forming the conductor so that a closest point of the conductor to any control gate is greater than a combined thickness of the tunnel oxide and the oxide-nitride-oxide layer in the memory.

5. The method of claim 4, wherein the separation is at least approximately 23-33 nanometers.

6. The method of claim 2, wherein the memory includes stacks of cells each having a tunnel oxide, a floating gate, an oxide-nitride-oxide layer, and a control gate, and wherein separating comprises:
forming the conductor so that a closest point of the conductor to any floating gate is at least as great as a thickness of the tunnel oxide in the memory cell of the floating gate.

7. The method of claim 6, wherein the separation is at least 8 nanometers.

8. A method of reducing floating gate coupling in a NAND non-volatile memory, comprising:
forming a conductive structure between adjacent floating gates of the memory; and
positioning the conductive structure to reduce tunneling between the conductive structure and adjacent floating gates and control gates of the memory.

9. The method of claim 8, wherein the memory includes stacks of cells each having a stacked structure of a tunnel oxide, a floating gate, an oxide-nitride-oxide layer, and a control gate, and wherein positioning further comprises:
spacing the conductive structure at least as far away from the control gates as a combined thickness of the tunnel oxide and oxide-nitride-oxide layers; and
spacing the conductive structure at least as far away from the floating gates as a thickness of the tunnel oxide.

10. A method of fabricating a non-volatile memory, comprising:
forming a conductive structure interposed between stacked memory cells, the stacked memory cells sharing a common source/drain region, each stack comprising a tunnel oxide, a floating gate, an oxide-nitride-oxide layer, and a control gate, wherein the conductive structure is connected only to the source/drain region and is interposed between adjacent floating gates.

11. The method of claim 10, wherein forming further comprises:
spacing the conductive structure so that a gap between the conductive structure and the floating gates is at least equal to a thickness of the tunnel oxide.

12. The method of claim 10, wherein forming further comprises:
spacing the conductive structure so that a gap between the conductive structure and the control gates is at least equal to a combined thickness of the tunnel oxide and the oxide-nitride-oxide layers.

13. A memory device, comprising:
an array of floating gate memory cells arranged in rows and columns such that the rows are each coupled to a word line and the columns are each coupled to a bitline;
control circuitry to read, write and erase the memory cells;
address circuitry to latch address signals provided on address input connections; and
a conductor interposed between floating gates of the memory, the conductor connected only to a common source/drain region between adjacent floating gates.

14. The memory device of claim 13, wherein each memory cell comprises a stack on a substrate, the stack comprising a tunnel oxide, a floating gate, an oxide-nitride-oxide layer, and a control gate, and wherein the conductor is separated from the control gates of adjacent memory cells by a distance at least as great as a sum of the combined thickness of the tunnel oxide and oxide-nitride-oxide layers.

15. The memory device of claim 13, wherein each memory cell comprises a stack on a substrate, the stack comprising a tunnel oxide, a floating gate, an oxide-nitride-oxide layer, and a control gate, and wherein the conductor is separated from the floating gates of adjacent memory cells by a distance at least as great as a thickness of the tunnel oxide.

16. A NAND memory cell, comprising:
a stacked structure formed on a substrate having a source/drain region, the stacked structure comprising:
a tunnel oxide;
a floating gate;
an oxide-nitride-oxide layer; and
a control gate; and
a conductor spaced apart from the stacked structure and connected to the source/drain region, the conductor spaced from the control gate by a first gap at least equal to a combined thickness of the tunnel oxide and the oxide-nitride-oxide layer, and the conductor spaced from the floating gate by a second gap at least equal to the thickness of the tunnel oxide.

17. The memory cell of claim 16, and further comprising:
a second memory cell having a second stacked structure the same as the first stacked structure, connected to the source/drain region, the conductor spaced apart from the second stacked structure stacked structure and connected to the source/drain region, the conductor spaced from the control gate of the second stacked structure by a gap equal to the first gap, and the conductor spaced from the floating gate of the second stacked structure by a fourth gap equal to second gap.

18. A memory module, comprising:
a plurality of contacts; and
two or more memory devices, each having access lines selectively coupled to the plurality of contacts, wherein at least one of the memory devices comprises:
an array of non-volatile memory cells arranged in rows and columns and accessed by bitlines and word lines;
control circuitry to read, write and erase the memory cells;
address circuitry to latch address signals provided on address input connections; and
a conductor interposed between adjacent floating gates of the memory, the conductor connected only to a common source/drain region between adjacent floating gates.

19. A flash memory module, comprising:
a housing having a plurality of contacts; and
one or more flash memory devices enclosed in the housing and selectively coupled to the plurality of contacts;
wherein at least one of the memory devices comprises:
an array of non-volatile memory cells arranged in rows and columns and accessed by bitlines and word lines;
control circuitry to read, write and erase the memory cells;
address circuitry to latch address signals provided on address input connections; and
a conductor interposed between adjacent floating gates of the memory, the conductor connected only to a common source/drain region between adjacent floating gates.

20. A processing system, comprising:
a processor; and
a memory device coupled to the processor to store data provided by the processor and to provide data to the processor, the memory comprising:
an array of floating gate memory cells arranged in rows and columns and accessed by bitlines and word lines, a pair of memory cells sharing a common source/drain region;
control circuitry to read, write and erase the memory cells;
address circuitry to latch address signals provided on address input connections; and
a conductor interposed between adjacent floating gates of the memory device, the conductor connected only to the common source drain region between adjacent memory cells.

21. The processing system of claim 20, wherein each floating gate memory cell comprises a stack including a tunnel oxide, a floating gate, an oxide-nitride-oxide layer, and a control gate, and wherein the conductor is interposed so that the conductor is separated from each of its adjacent control gates by a gap at least equal to a combined thickness of the tunnel oxide and the oxide-nitride-oxide layers.

22. The processing system of claim 20, wherein each floating gate memory cell comprises a stack including a tunnel oxide, a floating gate, an oxide-nitride-oxide layer, and a control gate, and wherein the conductor is interposed so that the conductor is separated from each of its adjacent floating gates by a gap at least equal to a thickness of the tunnel oxide.

23. The processing system of claim 20, wherein each floating gate memory cell comprises a stack including a tunnel oxide, a floating gate, an oxide-nitride-oxide layer, and a control gate; wherein the conductor is interposed so that the conductor is separated from each of its adjacent control gates by a gap at least equal to a combined thickness of the tunnel oxide and the oxide-nitride-oxide layers; and wherein the conductor is interposed so that the conductor is separated from each of its adjacent floating gates by a gap at least equal to a thickness of the tunnel oxide.

24. A method of reducing floating gate coupling in a memory, comprising:
forming a conductor interposed between adjacent floating gates of the memory, the conductor connected to a source/drain region common to the adjacent floating gates and not extending above a top level of control gates of the memory.

25. A memory cell, comprising:
a stacked structure formed on a substrate haying a source/drain region, the stacked structure comprising:
a tunnel oxide;
a floating gate;
an oxide-nitride-oxide layer; and
a control gate; and
a conductor spaced apart from the stacked structure and connected to the source/drain region, the conductor spaced from the control gate by a first gap at least equal to a combined thickness of the tunnel oxide and the oxide-nitride-oxide layer, and the conductor spaced from the floating gate by a second gap at least equal to the thickness of the tunnel oxide, and the conductor not extending above a top level of the control gate.
